(19) United States
(12) Patent Application Publication
(10) Pub. No.: US 2025/0027972 A1
(43) Pub. Date: Jan. 23, 2025

(54) DATA SIGNAL TRANSMISSION CONNECTOR AND MANUFACTURING METHOD FOR THE SAME

(71) Applicant: TSE CO., LTD, Cheonan-si (KR)

(72) Inventors: Bo Hyun KIM, Cheonan-si (KR); Dae Hyun RO, Cheonan-si (KR)

(73) Assignee: TSE CO., LTD, Cheonan-si (KR)

(21) Appl. No.: 18/770,291

(22) Filed: Jul. 11, 2024

(30) Foreign Application Priority Data
Jul. 21, 2023 (KR) 10-2023-0095082

(51) Int. Cl. G01R 1/04

(52) U.S. Cl. CPC G01R 1/0466; G01R 1/0416; G01R 1/0483

(57) ABSTRACT

A signal transmission connector formed by fastening the lower cover in a state where conductive electrodes supported by cover holes of the lower cover are inserted into frame holes of the upper frame to which the ball guide film is attached. The conductive electrodes may be replaced individually, and the conductive electrodes can operate independently. There is provided a rubber socket type signal transmission connector, which is advantageous for high-speed signal transmission.

### BACKGROUND

### Field

The disclosure relates to a signal transmission connector and, more particularly, to a signal transmission connector that is connected to an electronic component such as a semiconductor package to transmit an electrical signal, and a method of manufacturing the same.

### Description of Related Art

Currently, various types of connectors are used to transmit electrical signals in many fields such as the electronics industry and the semiconductor industry.

In the case of semiconductor devices, they are manufactured through a front-end process, a back-end process, and a test process. Among these, the test process is a process that tests whether semiconductor devices operate normally to distinguish between good and defective products.

One of the key components applied in the test process is a signal transmission connector called a test socket. The test socket is mounted on a printed circuit board electrically connected to an integrated circuit tester and is used to test a semiconductor device. The test socket is equipped with contact pins, and these contact pins electrically connect the terminals (leads) of the semiconductor device and the terminals of the printed circuit board. The tester generates an electrical signal for testing the semiconductor device to be connected to the test socket to output it to the semiconductor device, and tests whether the semiconductor device operates normally by using an electrical signal input through the semiconductor device. Depending on the result, the semiconductor device is determined to be good or defective.

Representative test sockets include pogo sockets and rubber sockets.

A pogo socket is formed by assembling individually manufactured pogo pins to the upper frame. Recently, the demand for rubber sockets has increased over pogo sockets in the semiconductor test process due to problems such as damage to package balls and increased unit prices.

The rubber socket has a structure in which conductive parts that contain a large number of conductive particles inside an elastic material such as silicon are arranged to be insulated from each other inside an insulating part made of an elastic material such as silicon. This rubber socket has the characteristic of being conductive only in the thickness direction, and as mechanical means such as soldering or springs is not used, it is excellent in durability and has the advantage of being able to achieve simple electrical connections. Additionally, since it can absorb mechanical shock or deformation, it has the advantage of enabling smooth connection to a semiconductor device, or the like.

FIG. 1 schematically shows a signal transmission connector in the form of a legacy rubber socket used in the test process of a semiconductor device.

The signal transmission connector 20 shown in FIG. 1 includes a plurality of conductive parts 22 in contact with the terminals 11 of a device under test 10, and an insulating part 21 supporting the plural conductive parts 22 to be spaced apart from each other. The conductive part 22 is made of a plurality of conductive particles contained in an elastic insulating material, and the insulating part 21 is made of an elastic insulating material. The legacy signal transmission connector 20 is installed in the tester 30. When the device under test 10 is pressurized by a pressurizing means (not shown), the terminals 11 of the device under test press the upper ends of the elastic conductive parts 22, so that the conductive parts 22 are in a conducting state where electricity may flow, and the lower ends of the conductive parts 22 are in contact with the pads 31 of the tester 30. Thereby, the pads 31 of the tester 30 and the terminals 11 of the device under test 10 are electrically connected.

In this way, the legacy signal transmission connector 20 made of a rubber socket has a form in which one conductive part 22 and the adjacent conductive part 22 are structurally connected to each other through the insulating part 21. So, during the manufacturing process, if any conductive part does not exhibit proper electrical characteristics, the entire socket, not just the single defective conductive part, is determined to be defective and a new socket should be manufactured. Additionally, even if any conductive part is damaged during the repetitive testing process, the entire socket should be replaced, which causes a problem of increasing the delivery time and the cost.

In addition, in the legacy signal transmission connector 20 made of a rubber socket, each element is structurally connected to each other, so it has a structure in which the pressing force (or stroke) applied to one conductive part 22 also affects other adjacent conductive parts 22 through the insulating part 21.

On the other hand, there is a height difference between the terminals 11 of the device under test 10 due to a tolerance; a device under test 10, which is relatively wide or has relatively thin packaging, may have a warpage in which the central part is raised upward compared to the edges after manufacturing or may be slightly distorted in another form, as illustrated in FIG. 1.

As described above, in the test process of a device under test 10 where there is a difference in height between the terminals 11 of the device under test, when the device under test 10 presses the signal transmission connector 20, the region around the conductive part 22 in contact with a terminal 11 of the device under test is compressed, but other regions are not compressed and try to maintain the previous height or expand. So, the degree of compression between the conductive parts varies depending on the heights of the terminals 11, causing concentrated stress to occur at the upper end of the conductive part 22 that receives a relatively large pressing force. If this phenomenon is repeated, the conductive part 22 where concentrated stress occurs is damaged, thereby causing a problem of shortening the lifespan of the signal transmission connector 20.

Additionally, in the case of a device under test with a large warpage, it is difficult to control the degree to which the conductive parts 22 are individually compressed depending on the height difference between the terminals 11, as illustrated in part (b) of FIG. 1, so in region “A” where the terminal 11 and the conductive part 22 contact first, the terminal 11 and the conductive part 22 are in contact, but in region “B”, the terminal 11 and the conductive part 22 are not in contact, causing a problem of poor contact.

In addition, in the legacy signal transmission connector 20 made of a rubber socket, electromagnetic waves are formed in the conductive parts 22 as the signal is transmitted at high speed, and the insulating part made of an elastic insulating material such as silicon with a relative permittivity of about 4 to 9 is formed between the conductive parts 22. So, a signal generated from one conductive part 22 affects other adjacent conductive parts 22 through the elastic insulating material such as silicon with a relatively high relative permittivity, which may cause electromagnetic waves to interfere with each other (crosstalk), thereby deteriorating signal transmission characteristics.

### PRIOR ART DOCUMENTS

### Patent Document

(patent document 1) Korean Patent Laid-Open Gazette No. 10-2006-0062824 (Jun. 12, 2006)

### SUMMARY

The disclosure has been devised in consideration of the above-mentioned points, and aims to provide a signal transmission connector that enables conductive electrodes to be individually replaced, improves the degree of freedom between the conductive electrodes so that it operates stably even on a device under test with a warpage, and is advantageous for high-speed signal transmission, and a method of manufacturing the same.

A signal transmission connector according to the present disclosure to achieve the above-mentioned purpose. The signal transmission connector for performing an electrical test of a device under test by connecting terminals of the device under test to pads of a tester generating a test signal may include: an upper frame through which frame holes are formed in a thickness direction at positions corresponding to the terminals of the device under test; a plurality of conductive electrodes, each of which is composed of plural conductive particles contained in an elastic insulating material, and includes an electrode body with an outer diameter smaller than that of the frame hole, and an electrode bump connected to the electrode body and having an outer diameter smaller than that of the electrode body; a ball guide film coupled to an upper side of the upper frame and provided with guide holes having an outer diameter smaller than that of the electrode body at positions corresponding to the frame holes; and a lower cover coupled to a lower side of the upper frame and provided with cover holes having an outer diameter smaller than that of the electrode body and larger than that of the electrode bump at centers of positions corresponding to the frame holes, wherein the lower cover may be detachably coupled to the upper frame in a manner that the electrode body connected to the terminal of the device under test is disposed in the frame hole and the electrode bump connected to the pad of the tester is disposed in the cover hole.

At least one of the conductive electrodes may be replaced with another conductive electrode after detaching the lower cover.

The space formed by a gap between an inner side surface of the frame hole and an outer side surface of the electrode body may be filled with air.

The lower cover and the upper frame may be screwed together.

The ball guide film may be attached to the upper frame with an adhesive.

The upper frame may be made of an inelastic insulating material.

The upper frame may be made of a conductive material, and an insulating layer may be formed on the inner side surface of the frame hole.

In addition, the signal transmission connector for performing an electrical test of a device under test according to the disclosure may be manufactured by using a manufacturing method including the steps of: (a) preparing a bump mold in which a plurality of bump mold holes are formed, and stacking a body mold in which body mold holes having an outer diameter larger than that of the bump mold hole are formed at positions corresponding to the bump mold holes, above the bump mold; (b) filling the bump mold holes and the body mold holes with a conductive particle mixture containing conductive particles in an elastic insulating material, and curing the conductive particle mixture; (c) removing the bump mold to prepare an electrode mold in which plural conductive electrodes, each having an electrode body and an electrode bump, are disposed on the body mold; (d) preparing an upper frame by forming frame holes penetrating the upper frame in a thickness direction; (e) attaching a ball guide film in which guide holes having an outer diameter smaller than that of the electrode body are formed at positions corresponding to the frame holes, to an upper side of the upper frame; (f) turning over the upper frame in a manner that the ball guide film is located on a lower side, and arranging shims on an upper side of the upper frame; (g) turning over the electrode mold to arrange the conductive electrodes at positions corresponding to the frame holes; (h) disposing the conductive electrodes in the frame holes by pressing the conductive electrodes; and (i) fastening a lower cover in which cover holes having an outer diameter smaller than that of the electrode body and larger than that of the electrode bump are formed at positions corresponding to the frame holes, to an upper side of the flipped upper frame.

The step (d) and step (e) may be carried out before the step (a).

The manufacturing method may further include, before curing at step (b), the step of arranging an upper mold and a lower mold in which magnetic poles are formed at positions corresponding to the body mold holes and the bump mold holes, and applying a magnetic field to the conductive particle mixture in an upward and downward direction.

In the signal transmission connector according to the disclosure, if only some of the conductive electrodes are defective or damaged, only the defective or damaged conductive electrodes may be replaced individually without replacing the whole socket. Hence, the socket manufacturing time can be shortened, and socket manufacturing and maintenance costs can be significantly reduced.

Additionally, in the signal transmission connector according to the disclosure, the conductive electrodes are disposed to be spaced apart on the upper frame made of an inelastic material, so each conductive electrode may be freely moved up and down independently. Also, the upper frame made of an inelastic material acts as a hard stop to prevent excessive stroke from being applied to the signal transmission connector. Hence, the signal transmission connector is capable of responding to a semiconductor package where the height difference between terminals of the device under test is large without contact defects, ensuring a stable stroke.

Additionally, in the signal transmission connector according to the disclosure, a space formed by a gap is provided between the inner surface of a frame hole and the outer surface of the electrode body so as to allow the conductive electrode to expand in the space, so that it is possible to prevent the problem of easily damaging the conductive electrode and shortening the lifespan of the signal transmission connector caused by the pressing force transferred through the device under test and concentrated on the upper end of the conductive electrode.

Additionally, in the signal transmission connector according to the disclosure, the overall permittivity of the dielectric between the conductive electrodes is lowered by an air layer filled with air having a relative permittivity of 1 in the space formed by the gap and the upper frame made of an insulating material. So, signal interference between the conductive electrodes may be minimized and the range of characteristic impedance values can be increased, which is advantageous for high-speed signal transmission.

Additionally, the signal transmission connector according to the disclosure may, when an upper frame made of a conductive material is applied, form a coaxial cable structure in which the conductive electrode is surrounded by an air layer with a relative permittivity of 1 and an insulating layer, and the air layer is surrounded by the upper frame made of a conductive material, so that it may also be applied to a test device for semiconductor packages that require high-speed signal transmission.

### BRIEF DESCRIPTION OF THE DRAWINGS

FIG. 1 illustrates a test process by using a legacy signal transmission connector.

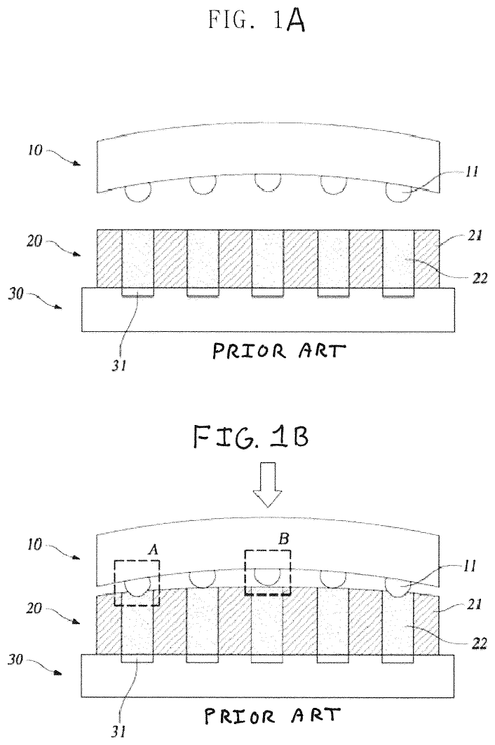

FIG. 2 illustrates a signal transmission connector according to an embodiment of the disclosure.

FIG. 3 illustrates a process for manufacturing a conductive electrode of the signal transmission connector according to an embodiment of the disclosure.

FIG. 4 illustrates a process of assembling the signal transmission connector according to an embodiment of the disclosure.

FIG. 5 illustrates a modified example of the signal transmission connector according to an embodiment of the disclosure.

FIG. 6 illustrates a process for replacing a damaged conductive electrode in the signal transmission connector according to an embodiment of the disclosure.

FIG. 7 illustrates a test process by using the signal transmission connector according to an embodiment of the disclosure.

### DETAILED DESCRIPTION

Hereinafter, the signal transmission connector and its manufacturing method according to the disclosure will be described in detail with reference to the drawings.

In the disclosure, the device under test is located on the upper side of the test device and the tester is located on the lower side, so “upper surface”, “upper side”, “upper end”, “lower surface”, “lower side”, and “lower end” of a component will be described with respect to this. Additionally, the same symbols are used for the same components and their descriptions may be omitted.

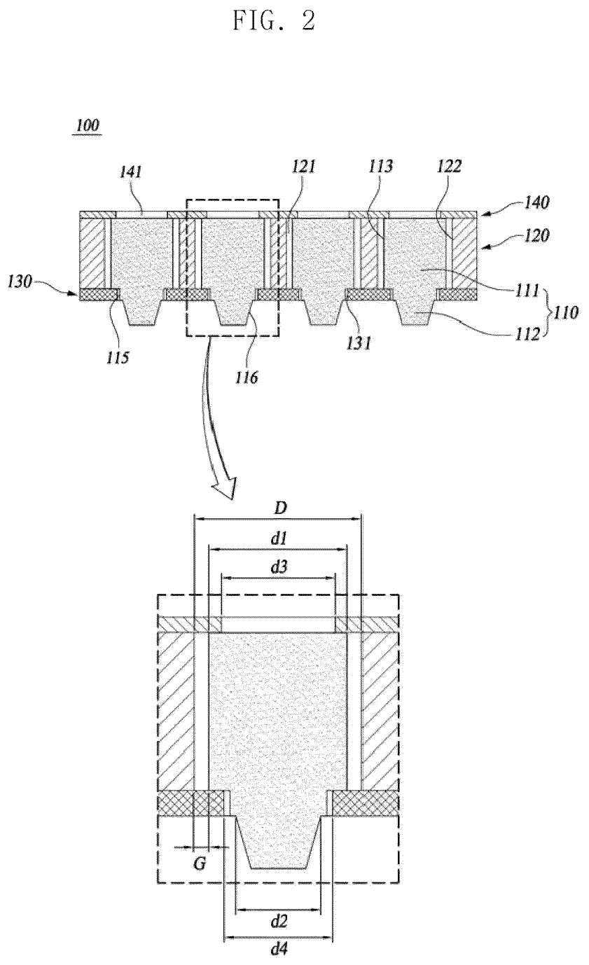

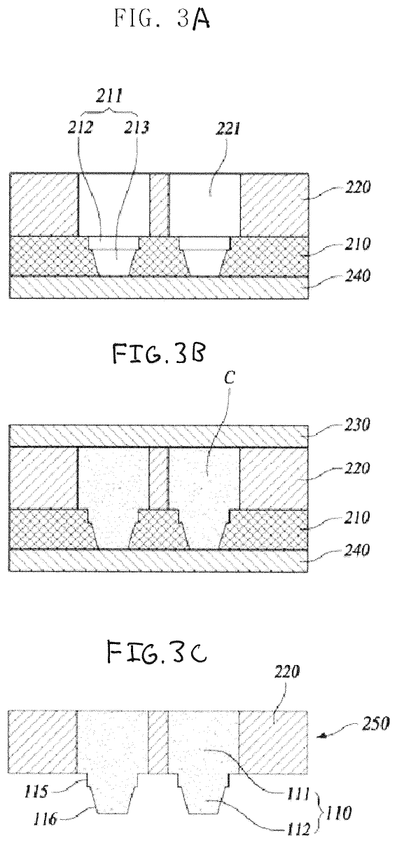

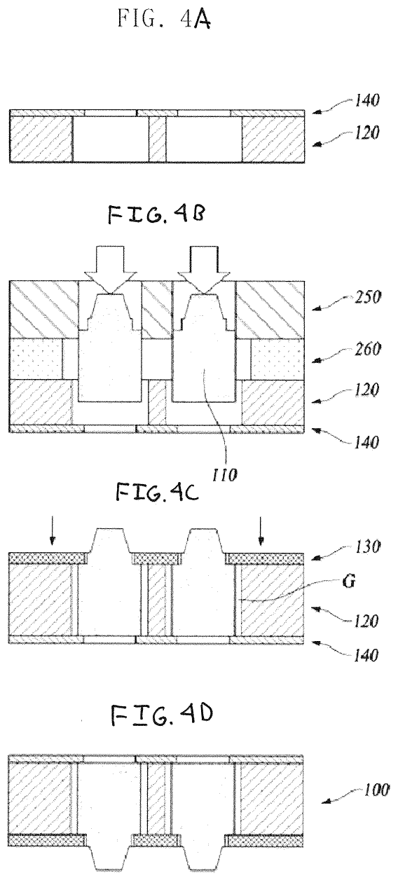

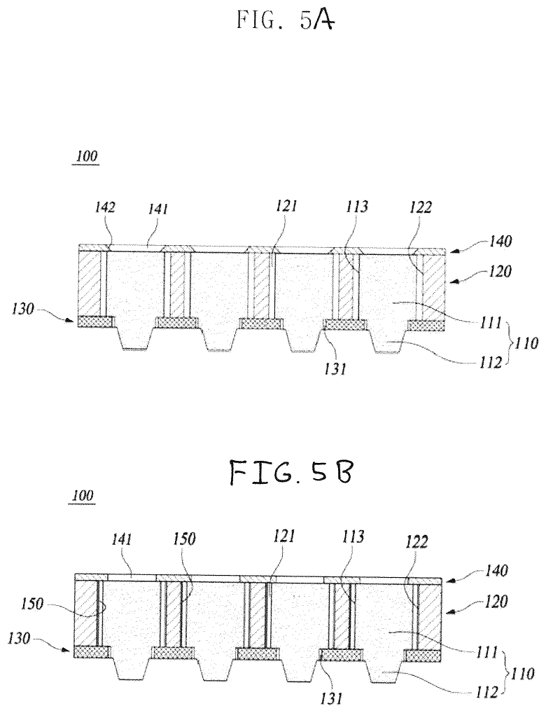

FIG. 2 illustrates a signal transmission connector according to an embodiment of the disclosure, FIG. 3 illustrates a process for manufacturing a conductive electrode, FIG. 4 illustrates a process of assembling the signal transmission connector, and FIG. 5 illustrates a modified example of the signal transmission connector.

As shown in the drawings, the signal transmission connector 100 according to an embodiment of the disclosure performs an electrical test of the device under test by connecting the terminals 11 of the device under test 10 to the pads 31 of the tester 30 generating a test signal, and may include: an upper frame 120 through which frame holes 121 are formed in the thickness direction at positions corresponding to the terminals of the device under test; a plurality of conductive electrodes 110 each of which is composed of a plurality of conductive particles contained in an elastic insulating material, and includes an electrode body 111 with an outer diameter smaller than the outer diameter of the frame hole, and an electrode bump 112 connected to the electrode body and having an outer diameter smaller than the outer diameter of the electrode body; a ball guide film 140 coupled to the upper side of the upper frame and provided with guide holes 141 with an outer diameter smaller than the outer diameter of the electrode body at positions corresponding to the frame holes; and a lower cover 130 coupled to the lower side of the upper frame and provided with cover holes 131 with an outer diameter smaller than the outer diameter of the electrode body and larger than the outer diameter of the electrode bump at the centers of positions corresponding to the frame holes, wherein the lower cover 130 is detachably coupled to the upper frame 120 so that the electrode body 111 connected to the terminal of the device under test is placed within the frame hole 121 and the electrode bump 112 connected to the pad of the tester is placed in the cover hole 131.

This signal transmission connector 100 may be used to test the device under test through the tester by transmitting an electrical signal in a state where the electrode body is connected to the terminal of the device under test placed on the upper side of the upper frame and the electrode bump is connected to the pad of the tester placed on the lower side of the upper frame, or may be used to transmit an electrical signal by electrically connecting the device under test and various electronic devices. Next, as an example, a description will be given of the signal transmission connector 100 according to an embodiment of the disclosure that is installed in the tester 30 to perform a function of transmitting an electrical signal between the tester 30 and the device under test 10.

The signal transmission connector 100 is made by manufacturing the upper frame 120, the conductive electrodes 110, the ball guide film 140, and the lower cover 130 through separate manufacturing processes, and then assembling them.

As shown in FIG. 2, the upper frame 120 forms the body of the signal transmission connector 100, and it is made by forming a plurality of frame holes 121 penetrating the upper frame 120 with a drill, laser, etc. in the vertical direction, that is, the thickness direction at positions corresponding to the terminals 11 of the device under test 10. The outer diameter of the frame hole 121 has a diameter of ‘D’.

The upper frame 120 may be made of an inelastic insulating material or an inelastic conductive material. As inelastic insulating materials, engineering plastics such as polyimide or various other inelastic insulating materials may be used. As inelastic conductive materials, conductive metals such as aluminum, copper, brass, SUS, iron, and nickel, or various materials that are conductive and have inelastic properties may be used. The upper frame 120 made of this inelastic material has a hardness level that does not experience compressive deformation due to the maximum pressing force applied through the test device 10 in the test process, and has the characteristic of not being easily elastically deformed like the elastic insulating part of a legacy rubber socket.

If the upper frame 120 is made of a conductive material, it is preferable to form an insulating layer 150 on the entire inner surface 122 of the frame hole, as shown in part (b) of FIG. 5. This is to prevent an electrical short from occurring when the conductive electrode directly contacts the upper frame made of a conductive material.

The conductive electrodes 110 may be manufactured in an illustrative manner as shown in FIG. 3.

As shown in part (a) of FIG. 3, a lower mold 240 is prepared; a bump mold 210 in which a plurality of bump mold holes 211 are formed is placed on the upper surface of the lower mold 240; a body mold 220 having body mold holes 221 with an outer diameter larger than the bump mold hole formed at positions corresponding to the bump mold holes is stacked on the upper surface of the bump mold. The bump mold 210 is used to form the electrode bump 112 of the conductive electrode, and the body mold 220 is used to form the electrode body 111 of the conductive electrode.

The bump mold 210 may have a form in which an upper bump mold and a lower bump mold are stacked, where the upper bump mold has an upper hole 212 for forming a cover insertion portion 115 to be inserted into the lower cover, and the lower bump mold has a lower hole 213 with an outer diameter smaller than the upper hole 212 for forming a protrusion 116 protruding toward the pad of the tester. The outer diameter of the upper hole 212 is slightly smaller than the outer diameter of the cover hole 131 of the lower cover. The electrode bump 112 may be formed in various desired shapes by modifying the bump mold hole 211 formed in the bump mold 210. For example, if the bump mold hole is formed only as the upper hole, a cylindrical electrode bump may be formed; if the bump mold hole is formed as an inverted truncated cone-shaped hole, an electrode bump in an inverted truncated cone shape may be formed. In the disclosure, the bump mold hole 211 is described as having an upper hole 212 and a lower hole 213, and the electrode bump 112 is described as having a cover insertion portion 115 and a protrusion 116.

Next, as shown in part (b) of FIG. 3, the bump mold hole 211 and the body mold hole 221 are filled with a conductive particle mixture C where conductive particles are contained in an elastic insulating material, and a curing process is performed. The curing process may be performed within the upper mold 230 and the lower mold 240 as shown. Various methods may be used to cure the conductive particle mixture C depending on the characteristics of the conductive particle mixture C, such as heating to a certain temperature and then cooling to room temperature.

As an elastic insulating material constituting the conductive particle mixture C, a heat-resistant polymer material with a cross-linked structure, for example, silicone rubber or the like may be used.

In addition, as conductive particles included in the conductive particle mixture C, particles having magnetism capable of reacting with a magnetic field may be used. For example, the conductive particles may include particles of magnetic metal such as iron, nickel or cobalt, alloy particles thereof, particles containing these metals, or those that these particles are used as core particles and metals with good conductivity such as gold, silver, palladium, and radium are plated on the surface of the core particles.

In addition, before the step of integrally curing the conductive particle mixture (C) filled in the bump mold hole 211 and the body mold hole 221, it may further include the step of forming an electrical path by placing the upper mold 230 and the lower mold 240 where magnetic poles are formed at positions corresponding to the body mold hole 221 and the bump mold hole 211, and by applying a magnetic field in the vertical direction to the conductive particle mixture (C) through the magnetic poles so that the conductive particles dispersed in the elastic insulating material are oriented in the thickness direction of the upper frame 120 under the influence of the magnetic field.

When all of the upper mold 230, body mold 220, bump mold 210, and lower mold 240 used in manufacturing the conductive electrodes 110 are removed, a plurality of conductive electrodes 110 according to the disclosure are individually formed. Such a conductive electrode 110 may be composed of an electrode body 111 having an outer diameter of ‘d1’, and an electrode bump 112 that is connected to the electrode body and has an outer diameter of ‘d2’ less than the outer diameter of the electrode body. Here, the outer diameter d1 of the electrode body is formed to have an outer diameter less than the outer diameter D of the frame hole.

Although the conductive electrodes 110 may be manufactured in a manner described above, as shown in part (c) of FIG. 3, it is possible to maintain a state of the electrode mold 250 where the conductive electrodes 110 are disposed in the body mold 220 by removing the upper mold 230, lower mold 240, and bump mold 210 only while keeping the body mold 220. The electrode mold 250 where the conductive electrodes 110 are disposed in the body mold 220 is to simplify the assembly process by inserting the minute conductive electrodes 110 respectively into the frame holes 121 of the upper frame at once by using a jig or the like. This will be described later.

In the signal transmission connector 100, a plurality of conductive electrodes 110 may be disposed at positions corresponding to the terminals 11 provided on the device under test 10 for connections so that the upper end of the conductive electrode 110 is connected to the terminal 11 of the device under test 10 and the lower end thereof is connected to the pad 31 of the tester 30.

The ball guide film 140 serves to insulate between the conductive electrodes 110, prevent the terminal 11 of the device under test from contacting the upper frame 120, and guide the terminal 11 of the device under test to the conductive electrode 110, and is coupled to the upper side of the upper frame 120.

The ball guide film 140 is formed by forming a plurality of guide holes 141 penetrating the ball guide film with a drill, laser, or the like in the thickness direction at positions corresponding to the frame holes 121 of the upper frame. It is preferable that the outer diameter d3 of the guide hole 141 is formed to be smaller than the outer diameter d1 of the electrode body. The ball guide film, which has a guide hole formed smaller than the outer diameter of the electrode body, also serves to support the conductive electrode 110 so that it does not fall out of the frame hole 121.

As a material for the ball guide film 140, synthetic resin such as polyimide, which has insulating properties and rigidity to stably fix the electrode body 111, may be used.

This ball guide film 140 may be coupled to the upper frame 120 by attaching it to the upper side of the upper frame 120 using an adhesive or the like. However, without being limited thereto, the ball guide film 140 may also be coupled to the upper frame by fastening it with a method such as screwing.

In the ball guide film 140, as shown in part (a) of FIG. 5, to allow the terminal 11 of the device under test to be more easily guided toward the conductive electrode 110, a guide portion 142 whose width gradually decreases as going toward the electrode body 111 may be formed on the side surface of the guide hole 141. In the process of testing the device under test, when the terminal 11 of the device under test is approached while being misaligned with the center of the conductive electrode 110, the terminal 11 of the device under test comes into contact with the guide portion 142 and is moved toward the center of the conductive electrode 110 along the inclined surface of the guide portion 142, so the guide portion 142 has the effect of stably connecting the terminal of the device under test and the conductive electrode in alignment.

The lower cover 130 constitutes the signal transmission connector 100 by supporting the conductive electrodes 110 in cooperation with the ball guide film 140 and the upper frame 120, and serves to allow the conductive electrodes 110 to be individually replaced, support the conductive electrode 110 to be located in the center of the frame hole 121 of the upper frame, insulate between the conductive electrodes 110, and prevent the pads 31 of the tester from contacting the upper frame 120.

The lower cover 130 is made by forming cover holes 131 penetrating the lower cover in the thickness direction at central portions of the positions corresponding to the frame holes 121 of the upper frame. The cover holes 131 of the lower cover may be formed through penetration by using a drill, laser, or the like.

The outer diameter d4 of the cover hole 131 is formed to be smaller than the outer diameter d1 of the electrode body but larger than the outer diameter d2 of the electrode bump. Hence, the electrode bump 112 is allowed to be moved in the cover hole 131, but the electrode body 111 is not allowed to pass through the cover hole 131. In addition, since the cover hole 131 is coupled to be located at the center of the frame hole 121, the electrode bump 112 of the conductive electrode may be aligned at the correct position in the cover hole 131, and the electrode body 111 connected to the electrode bump 112 may be positioned at the center of the frame hole 121 of the upper frame.

As a material for the lower cover 130, a synthetic resin material such as polyimide, which has insulating properties and rigidity to stably fix the electrode bumps 112, may be used.

The lower cover 130 is detachably coupled to the lower side of the upper frame 120. Hence, if some of the conductive electrodes are damaged, the damaged conductive electrode may be easily replaced with a normal conductive electrode by detaching the lower cover. The coupling between the lower cover 130 and the upper frame 120 is preferably formed in a structure that can be easily separated, and they may be coupled in a variety of ways such as screwing, snap-fitting, or fitting. Since these coupling schemes are generally known, specific illustrations thereof are omitted.

As shown in FIG. 4, the upper frame 120, the conductive electrodes 110, the ball guide film 140, and the lower cover 130, which are separately manufactured, are assembled together to constitute the signal transmission connector 100 according to an embodiment of the disclosure.

As shown in part (a) of FIG. 4, the ball guide film 140 may be attached to the upper side of the upper frame 120 by using an adhesive or the like. At this time, since the guide hole 141 of the guide film is located at the central portion of the frame hole 121 of the upper frame, the guide film may be disposed to cover a portion of the outer edge of the frame hole.

Next, as shown in part (b) of FIG. 4, the upper frame 120 to which the ball guide film 140 is coupled is turned over and arranged so that the ball guide film is located on the lower side and the upper frame is located on the upper side. Then, a shim 260 is disposed in the outer region of the upper frame 120 where the frame hole 121 is not formed, and the electrode mold 250 is placed on the upper side of the shim 260. At this time, the electrode mold 250 is arranged so that the conductive electrode 110 is located at a position corresponding to the frame hole 121 of the upper frame. Here, the shim 260 serves as a space where the conductive electrode may be separated from the electrode mold by providing a gap between the upper frame and the electrode mold.

In this state, when the conductive electrodes 110 are pressed from the top to the bottom by using a jig or the like to push the conductive electrodes 110 out of the electrode molds 250, the conductive electrodes may be disposed respectively in the frame holes 121 of the upper frame. Instead of inserting the very small-sized conductive electrodes 110 into the frame holes one by one, the conductive electrodes may be disposed in the frame holes at once by using a jig while the conductive electrodes are arranged in the electrode mold, greatly shortening the work process.

Next, as shown in part (c) of FIG. 4, the lower cover 130 is fastened. The lower cover 130 is placed on the upper side of the overturned upper frame 120 while the electrode bumps 112 of the conductive electrodes are positioned in the cover holes 131 of the lower cover, and the lower cover 130 is fastened to the upper frame 120 by using a screw or the like (not shown). Here, it should be noted that after the cover hole 131 of the lower cover is positioned at the center of the frame hole 121, the lower cover is fastened to the upper frame.

In the lower cover 130 fastened in this way, since the cover hole 131 of the lower cover is located at the center of the frame hole 121 of the upper frame, the electrode bump 112 located in the cover hole can align the electrode body 111 so that it is located in the center of the frame hole 121 of the upper frame. In addition, since the outer diameter d1 of the electrode body 111 is formed to be smaller than the outer diameter D of the frame hole 121, the electrode body 111 is disposed in the frame hole 121 so as to have a gap G of a certain interval from the inner surface 122 of the frame hole 121 and be spaced apart from the inner surface 122 of the frame hole 121. However, as shown in part (b) of FIG. 5, when the upper frame is made of a metal material and an insulating layer 150 is formed on the inner side surface of the frame hole, the gap G may be understood as being present between the inner side surface of the insulating layer and the outer side surface of the electrode body.

In the disclosure, the space formed by the gap between the inner surface 122 of the frame hole and the outer surface 113 of the electrode body is filled with air having a relative permittivity of 1.

Additionally, the space formed by the gap G between the frame hole and the electrode body is, when the electrode body 111 is compressed by the terminal 11 of the device under test, also used as a space to absorb the convex expansion in the middle part of the electrode body 111. Hence, the size of the space formed by the gap G may be set differently for different frame holes 121 in consideration of the degree of expansion due to compression of the conductive electrodes. That is, for the electrode body portion that is greatly compressed by the terminal 11 of the device under test, the gap G may be widened to enlarge the space formed by the gap, thereby enabling easier compression and expansion.

Part (d) of FIG. 4 shows the signal transmission connector 100 in a usable state according to an embodiment of the disclosure obtained by turning over the upper frame to which the lower cover is fastened to its original state, as shown in FIG. 3.

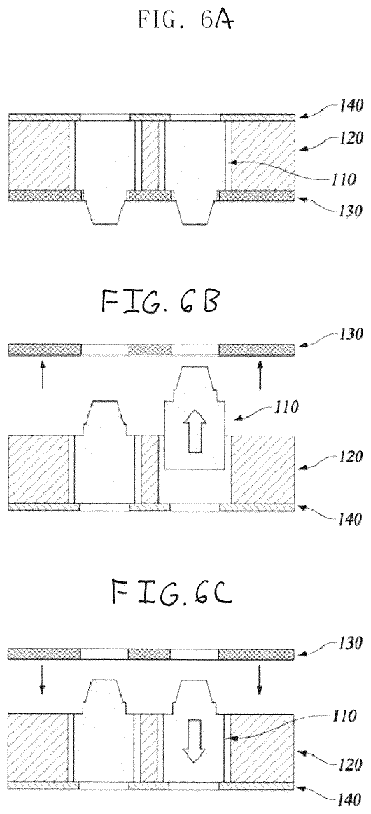

FIG. 6 illustrates a process of individually replacing defective or damaged conductive electrodes when the characteristics of one or more conductive electrodes are defective in the process of manufacturing a signal transmission connector or when one or more conductive electrodes are damaged during repetitive testing.

Part (a) of FIG. 6 illustrates a case in which the conductive electrode 110 located on the left side of the signal transmission connector is defective or damaged.

As shown in part (b) of FIG. 6, the signal transmission connector is turned over first. Turning over the signal transmission connector is to prevent the conductive electrodes from falling out when detaching the lower cover. In a state where the signal transmission connector is turned over, the lower cover 130 is detached by loosening the screws or the like that fasten the lower cover 130 to the upper frame 120, and the damaged or defective conductive electrode 100 is separated from the frame hole. Then, a normally operating conductive electrode 100 as a replacement is inserted into the frame hole 121.

Next, as shown in part (c) of FIG. 6, the lower cover 130 is fastened to the upper side of the overturned upper frame 120 by using screws, or the like. Thereby, defective or damaged conductive electrodes may be easily replaced individually.

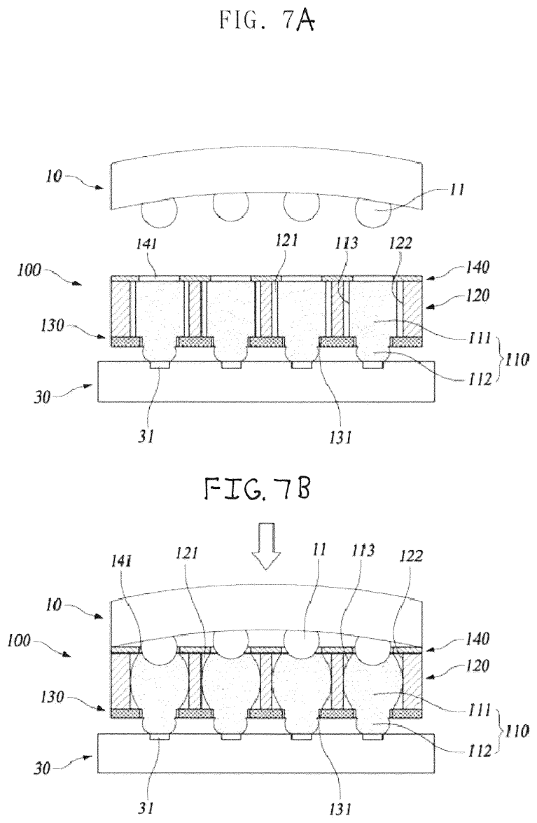

FIG. 7 illustrates a test process by using the signal transmission connector according to an embodiment of the disclosure.

As shown in the drawing, for testing a device under test 10 with a height difference between terminals 11 or with warpage, when a pressing means (not shown) presses the device under test 10 toward the upper side of the signal transmission connector 100 mounted on the tester 30, as shown in part (b) of FIG. 7, the terminals 11 of the device under test press the electrode bodies 111, where the terminal 11 at the lowest position first contacts the upper end of the corresponding electrode body 111. In this case, since the adjacent electrode bodies 111 are structurally separated from each other, they are compressed independently of each other, and the middle portion of the electrode body 111 expands into the space where the air layer is formed in the frame hole 121. Although the leftmost and rightmost electrode bodies in contact with the terminals 11 of the device under test located at the lowest position may be more compressed and expanded compared to the central electrode body, as the electrode bodies are separated from each other, this compression force does not affect other electrode bodies.

When the electrode bodies 111 are compressed, this compression force is also transferred to the electrode bumps 112, so that the electrode bodies 111 and the electrode bumps 112 are in a conduction state and connected to the pads 31 of the tester. Thereby, the tester 30 and the device under test 10 are electrically connected through the signal transmission connector 100, and the test may be performed.

As a result, in the signal transmission connector 100 according to the disclosure, if only some of the conductive electrodes are defective or damaged, only the defective or damaged conductive electrodes may be replaced individually without replacing the whole socket. Hence, the socket manufacturing time can be shortened, and socket manufacturing and maintenance costs can be significantly reduced.

In the signal transmission connector 100 according to the disclosure, the conductive electrodes are disposed to be spaced apart on the upper frame made of an inelastic material, so each conductive electrode may be freely moved up and down independently. Also, the upper frame made of an inelastic material acts as a hard stop to prevent excessive stroke from being applied to the signal transmission connector. Hence, the signal transmission connector is capable of responding to a semiconductor package where the height difference between terminals of the device under test is large without contact defects, ensuring a stable stroke.

Additionally, in the signal transmission connector 100 according to the disclosure, a space formed by a gap is provided between the inner surface of a frame hole and the outer surface of the electrode body so as to allow the conductive electrode to expand in the space. Hence, it is possible to prevent the problem of easily damaging the conductive electrode and shortening the lifespan of the signal transmission connector caused by the pressing force transferred through the device under test and concentrated on the upper end of the conductive electrode.

Additionally, in the signal transmission connector 100 according to the disclosure, the overall permittivity of the dielectric between the conductive electrodes is lowered by filling air having a relative permittivity of 1 in the space formed by the upper frame made of an insulating material and a gap. So, signal interference between the conductive electrodes may be minimized and the range of characteristic impedance values can be increased, which is advantageous for high-speed signal transmission.

Additionally, the signal transmission connector 100 according to the disclosure may, when an upper frame made of a conductive material is applied, form a coaxial cable structure in which the conductive electrode is surrounded by an air layer with a relative permittivity of 1 and an insulating layer, and the air layer is surrounded by the upper frame made of a conductive material, so that it may also be applied to a test device for semiconductor packages that require high-speed signal transmission.

Hereinabove, the disclosure has been described with preferred examples, but the scope of the disclosure is not limited to those described and shown above.

For example, in the drawings, a plurality of conductive electrodes are all shown to have the same shape and the same width. However, at least one of the plural conductive electrodes may be designed to have a different width according to signal properties for characteristic impedance matching and types of related devices under test.

Hereinabove, the disclosure has been shown and described in connection with preferred embodiments for illustrating the principles of the disclosure, but the disclosure is not limited to the construction and operation as shown and described. Rather, those skilled in the art will understand that many changes and modifications may be made to the disclosure without departing from the spirit and scope of the appended claims.

1. A signal transmission connector for performing an electrical test of a device under test by connecting terminals of the device under test to pads of a tester generating a test signal, the signal transmission connector comprising:
an upper frame through which frame holes are formed in a thickness direction at positions corresponding to the terminals of the device under test;
a plurality of conductive electrodes, each of which is composed of plural conductive particles contained in an elastic insulating material, and includes an electrode body with an outer diameter smaller than that of the frame hole, and an electrode bump connected to the electrode body and having an outer diameter smaller than that of the electrode body;
a ball guide film coupled to an upper side of the upper frame and provided with guide holes having an outer diameter smaller than that of the electrode body at positions corresponding to the frame holes; and
a lower cover coupled to a lower side of the upper frame and provided with cover holes having an outer diameter smaller than that of the electrode body and larger than that of the electrode bump at centers of positions corresponding to the frame holes,
wherein the lower cover is detachably coupled to the upper frame in a manner that the electrode body connected to the terminal of the device under test is disposed in the frame hole and the electrode bump connected to the pad of the tester is disposed in the cover hole.

2. The signal transmission connector of claim 1, wherein at least one of the conductive electrodes is capable of being replaced with another conductive electrode after detaching the lower cover.

3. The signal transmission connector of claim 1, wherein a space formed by a gap between an inner side surface of the frame hole and an outer side surface of the electrode body is filled with air.

4. The signal transmission connector of claim 1, wherein the lower cover and the upper frame are screwed together.

5. The signal transmission connector of claim 1, wherein the ball guide film is attached to the upper frame with an adhesive.

6. The signal transmission connector of claim 1, wherein the upper frame is made of an inelastic insulating material.

7. The signal transmission connector of claim 1, wherein the upper frame is made of a conductive material, and an insulating layer is formed on the inner side surface of the frame hole.

8. A method of manufacturing a signal transmission connector for performing an electrical test of a device under test, the method comprising:
preparing a bump mold in which a plurality of bump mold holes are formed, and stacking a body mold in which body mold holes having an outer diameter larger than that of the bump mold hole are formed at positions corresponding to the bump mold holes, above the bump mold;
filling the bump mold holes and the body mold holes with a conductive particle mixture containing conductive particles in an elastic insulating material, and curing the conductive particle mixture;
removing the bump mold to prepare an electrode mold in which multiple conductive electrodes, each having an electrode body and an electrode bump, are disposed on the body mold;
preparing an upper frame by forming frame holes penetrating the upper frame in a thickness direction;
attaching a ball guide film in which guide holes having an outer diameter smaller than that of the electrode body are formed at positions corresponding to the frame holes, to an upper side of the upper frame;
turning over the upper frame in a manner that the ball guide film is located on a lower side, and arranging shims on an upper side of the upper frame;
turning over the electrode mold to arrange the conductive electrodes at positions corresponding to the frame holes;
disposing the conductive electrodes in the frame holes by pressing the conductive electrodes; and
fastening a lower cover in which cover holes having an outer diameter smaller than that of the electrode body and larger than that of the electrode bump are formed at positions corresponding to the frame holes, to an upper side of the flipped upper frame.

9. The method of claim 8, wherein the preparing the upper frame and the attaching are carried out before the preparing the bump mold.

10. The method of claim 8, further comprising, before the curing the conductive particles mixture, arranging an upper mold and a lower mold in which magnetic poles are formed at positions corresponding to the body mold holes and the bump mold holes, and applying a magnetic field to the conductive particle mixture in an upward and downward direction.
